(19) United States
(12) Patent Application Publication
(10) Pub. No.: US 2024/0363568 A1
(43) Pub. Date: Oct. 31, 2024

(54) SEMICONDUCTOR STRUCTURE

(71) Applicant: MediaTek Singapore Pte. Ltd., Singapore (SG)

(72) Inventors: Zhigang DUAN, Singapore (SG); Chang LIANG, Singapore (SG); Jubao ZHANG, Singapore (SG)

(21) Appl. No.: 18/609,368

(22) Filed: Mar. 19, 2024

Related U.S. Application Data
(60) Provisional application No. 63/498,847, filed on Apr. 28, 2023.

(51) Int. Cl. H01L 23/00

(52) U.S. Cl. CPC H01L 24/08; H01L 24/80; H01L 2224/08145; H01L 2224/80895; H01L 2224/80896; H01L 2924/1205

(57) ABSTRACT

A semiconductor structure includes a semiconductor substrate, a first capacitor, a first conductive via, a second conductive via, a second capacitor, a first conductive pad, and a second conductive pad. The first capacitor is disposed over the semiconductor substrate. The first conductive via is disposed over the first capacitor. The second conductive via is bonded to the first conductive via. The second capacitor is disposed over the second conductive via. The first conductive pad and the second conductive pad are disposed over the second capacitor and are electrically coupled to the first capacitor and the second capacitor.

### CROSS REFERENCE TO RELATED APPLICATIONS

This application claims the benefit of U.S. Provisional Application No. 63/498,847 filed on Apr. 28, 2023, the entirety of which is incorporated by reference herein.

### BACKGROUND OF THE INVENTION

### Field of the Invention

The present invention relates to semiconductor technology, and, in particular, to a semiconductor structure including a capacitor structure.

### Description of the Related Art

Semiconductor structures are widely used in various electronic applications, such as personal computers, mobile phones, digital cameras, and other electronic equipment. As a result of the progress being made in the semiconductor industry, a smaller semiconductor structure that takes up less space than the previous generation of semiconductor structures is required.

In addition, as high-performance integrated circuits demand larger currents at higher frequencies with lower power-supply voltages, power system design becomes increasingly challenging. Decoupling capacitors may be adopted to act as temporary charge reservoirs to prevent momentary fluctuations in supply voltage. The decoupling capacitors are more and more important to reduce power noise.

However, although existing semiconductor structures generally meet requirements, they have not been satisfactory in every respect. For example, while the size of electronic components such as transistors and resistors is getting smaller, capacitor structures still need to take up more space than other electronic components owing to their physical properties. This is unfavorable for the miniaturization of semiconductor structures. Therefore, further improvements to semiconductor structures are required.

### BRIEF SUMMARY OF THE INVENTION

Semiconductor structures are provided. An exemplary embodiment of a semiconductor structure includes a semiconductor substrate, a first capacitor, a first conductive via, a second conductive via, a second capacitor, a first conductive pad, and a second conductive pad. The first capacitor is disposed over the semiconductor substrate. The first conductive via is disposed over the first capacitor. The second conductive via is bonded to the first conductive via. The second capacitor is disposed over the second conductive via. The first conductive pad and the second conductive pad are disposed over the second capacitor and are electrically coupled to the first capacitor and the second capacitor.

Another embodiment of a semiconductor structure includes a semiconductor substrate, a first metal layer, a first capacitor, a second metal layer, a third metal layer, a second capacitor, and a fourth metal layer. The first metal layer is disposed over the semiconductor substrate. The first capacitor is disposed over the first metal layer. The second metal layer disposed over the first capacitor. The third metal layer is disposed over the second metal layer and is electrically coupled to the second metal layer. The second capacitor is disposed over the third metal layer and vertically overlaps the first capacitor. The fourth metal layer is disposed over the second capacitor and is electrically coupled to the first metal layer.

Yet another embodiment of a semiconductor structure includes a semiconductor substrate, a first capacitor, a second capacitor, and a hybrid-bonding structure. The first capacitor is disposed over the semiconductor substrate. The second capacitor is disposed over and vertically overlaps the first capacitor. The hybrid-bonding structure is disposed between the first capacitor and the second capacitor and electrically couples the first capacitor and the second capacitor.

### BRIEF DESCRIPTION OF THE DRAWINGS

The present invention can be more fully understood by reading the subsequent detailed description and examples with references made to the accompanying drawings, wherein:

FIGS. 1A to 1D are cross-sectional views of various stages of manufacturing an exemplary semiconductor structure in accordance with some embodiments of the present disclosure; and

FIG. 2 is a cross-sectional view of an exemplary semiconductor structure in accordance with some embodiments of the present disclosure.

### DETAILED DESCRIPTION OF THE INVENTION

The following description is made for the purpose of illustrating the general principles of the invention and should not be taken in a limiting sense. The scope of the invention is best determined by reference to the appended claims.

The present disclosure will be described with respect to particular embodiments and with reference to certain drawings, but the disclosure is not limited thereto and is only limited by the claims. The drawings described are only schematic and are non-limiting. In the drawings, the size of some of the elements may be exaggerated for illustrative purposes and not drawn to scale. The dimensions and the relative dimensions do not correspond to actual dimensions in the practice of the disclosure.

Additional elements may be added on the basis of the embodiments described below. For example, the description of “a first element on/over a second element” may include embodiments in which the first element is in direct contact with the second element, and may also include embodiments in which additional elements are disposed between the first element and the second element such that the first element and the second element are not in direct contact.

The spatially relative descriptors of the first element and the second element may change as the structure is operated or used in different orientations. In addition, the present disclosure may repeat reference numerals and/or letters in the various embodiments. This repetition is for simplicity and clarity and does not in itself dictate a relationship between the various embodiments discussed.

A semiconductor structure including a capacitor structure is described in accordance with some embodiments of the present disclosure. The capacitor structure includes capacitors which are stacked through a hybrid-bonding structure. As a result, the capacitance density can be increased.

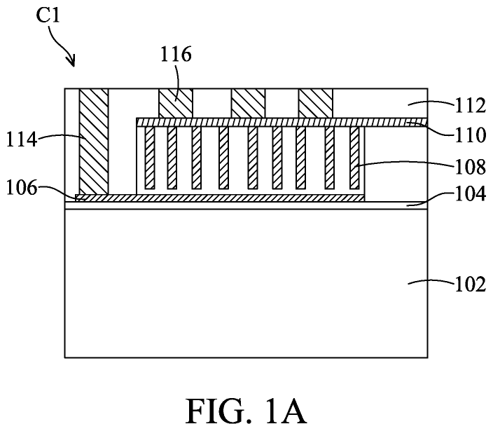

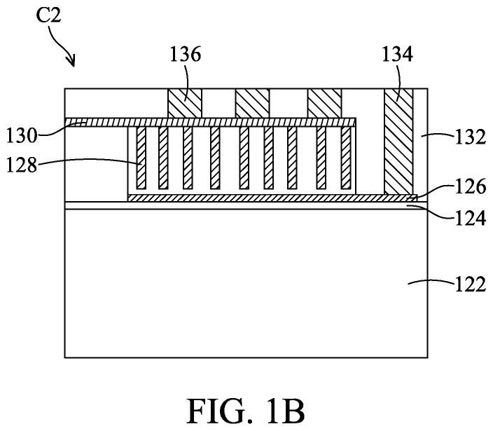

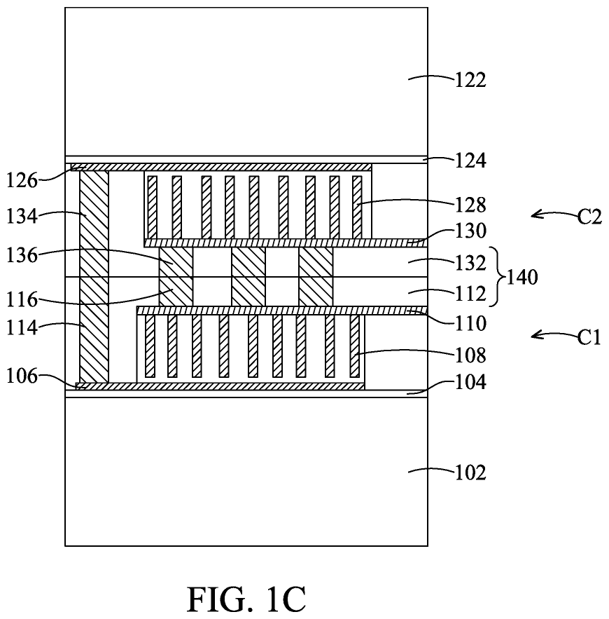

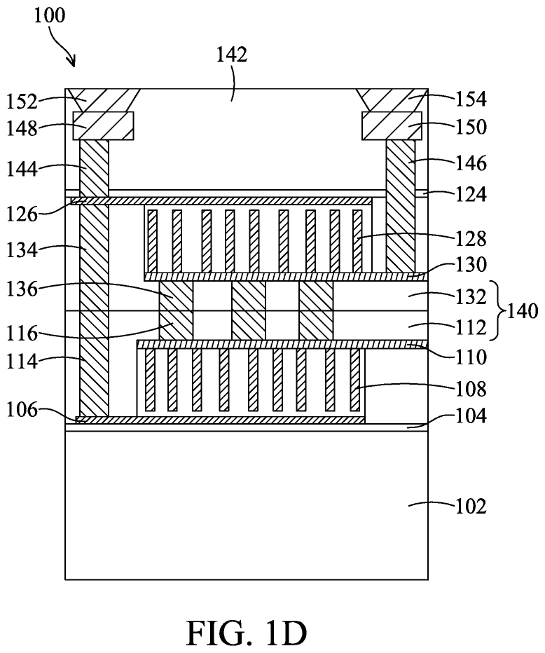

FIGS. 1A to 1D are cross-sectional views of various stages of manufacturing a semiconductor structure 100 in accordance with some embodiments of the present disclosure. Additional features can be added to the semiconductor structure 100. Some of the features described below can be replaced or eliminated for different embodiments. To simplify the diagram, only a portion of the semiconductor structure 100 is illustrated.

As illustrated in FIG. 1A, a semiconductor substrate 102 is provided, in accordance with some embodiments. The semiconductor substrate 102 may be formed of any suitable semiconductor material, such as silicon, germanium, silicon carbon, silicon germanium, gallium arsenide, indium arsenide, indium phosphide, the like, or a combination thereof. The semiconductor substrate 102 may include a bulk semiconductor or a composite substrate formed of different materials. The semiconductor substrate 102 may include a semiconductor-on-insulator (SOI) substrate formed by a semiconductor material on an insulating layer, such as a silicon-on-insulator substrate.

The semiconductor substrate 102 may be doped (e.g., using p-type or n-type dopants) or undoped. Any desired semiconductor elements (including active elements and/or passive elements) may be formed in and on the semiconductor substrate 102. However, in order to simplify the figures, only the flat semiconductor substrate 102 is illustrated. In some embodiments, an insulating layer 104 is formed over the semiconductor substrate 102. The insulating layer 104 may be formed of oxide, such as silicon oxide.

Afterwards, a first metal layer 106, a capacitor 108, and a second metal layer 110 are sequentially formed over the insulating layer 104, in accordance with some embodiments. The first metal layer 106 and the second metal layer 110 may each independently be formed of metal, including tungsten, titanium, tantalum, ruthenium, cobalt, copper, aluminum, platinum, tin, silver, gold, the like, an alloy thereof, or a combination thereof. The capacitor 108 may include a silicon capacitor.

The first metal layer 106 and the second metal layer 110 may extend beyond opposite sidewalls of the capacitor 108. In particular, the first metal layer 106 may have a sidewall outside of a first sidewall of the capacitor 108, and a sidewall aligned with a second sidewall of the capacitor 108; the second metal layer 110 may have a sidewall outside of the second sidewall of the capacitor 108, and a sidewall aligned with the first sidewall of the capacitor 108.

Then, a dielectric layer 112 is formed over the insulating layer 104 and surrounds the first metal layer 106, the capacitor 108, and the second metal layer 110, in accordance with some embodiments. The dielectric layer 112 may be formed of dielectric materials, including silicon oxide, silicon nitride, silicon oxynitride, the like, or a combination thereof, and may be formed by a deposition process.

Afterwards, a plurality of conductive vias 114 and 116 are formed in the dielectric layer 112, in accordance with some embodiments. A structure C1 may be formed. The top surfaces of the conductive vias 114 and 116 may be exposed by the dielectric layer 112. The conductive vias 114 and 116 may be formed by forming openings in the dielectric layer 112, and then filling the openings with conductive materials using a deposition process. The conductive materials may be metal, including tungsten, titanium, tantalum, ruthenium, cobalt, copper, aluminum, platinum, tin, silver, gold, the like, an alloy thereof, or a combination thereof.

The conductive via 114 may be electrically coupled to the first metal layer 106, and the conductive via 116 may be electrically coupled to the second metal layer 110. In the direction vertical to the top surface of the semiconductor substrate 102, the length of the conductive via 114 may be greater than the length of the conductive via 116. The length of the conductive via 114 may be greater than the total length of the conductive via 116 and the capacitor 108.

Although the structure C1 includes one conductive via 114 and three conductive vias 116 as illustrated in FIG. 1A, the numbers of conductive vias 114 and 116 are shown for illustrative purposes only. For example, the number of conductive vias 114 may be greater than or equal to the number of conductive vias 116.

Then, as illustrated in FIG. 1B, an insulating layer 124 may be formed over the semiconductor substrate 122. A first metal layer 126, a capacitor 128, and a second metal layer 130 may be sequentially formed over the insulating layer 124. A dielectric layer 132 may be formed over the insulating layer 124 and may surround the first metal layer 126, the capacitor 128, and the second metal layer 130. A plurality of conductive vias 134 and 136 may be formed in the dielectric layer 132, and a structure C2 may be formed. These components may be similar to the semiconductor substrate 102, the insulating layer 104, the first metal layer 106, the capacitor 108, the second metal layer 110, the dielectric layer 112, the conductive vias 114 and 116, respectively, and will not be described in detail.

The conductive via 134 may be electrically coupled to the first metal layer 126, and the conductive vias 136 may be electrically coupled to the second metal layer 130. In the direction vertical to the top surface of the semiconductor substrate 122, the length of the conductive via 134 may be greater than the length of the conductive via 136. The length of the conductive via 134 may be greater than the total length of the conductive via 136 and the capacitor 128.

Then, as illustrated in FIG. 1C, the structure C2 is stacked over the structure C1, in accordance with some embodiments. The structure C1 and the structure C2 may be stacked using hybrid bonding or another suitable bonding method. The hybrid bonding may include metal-to-metal bonding and dielectric-to-dielectric bonding. In some embodiments, the conductive via 114 is bonded to the conductive via 134 and the conductive vias 116 are bonded to the conductive vias 136 through metal-to-metal bonding. In some embodiments, the dielectric layer 112 is bonded to the dielectric layer 132 through dielectric-to-dielectric bonding. A hybrid-bonding structure 140 may be formed between the structure C1 and the structure C2. The hybrid-bonding structure 140 may include portions of the conductive vias 114, 116, 134, 136 and the dielectric layers 112, 132.

The first metal layer 106 of the structure C1 may be electrically coupled to the first metal layer 126 of the structure C2 through the conductive vias 114 and 134, and the second metal layer 110 of the structure C1 may be electrically coupled to the first metal layer 130 of the structure C2 through the conductive vias 116 and 136.

The capacitor 108 may at least partially vertically overlap the capacitor 128. In particular, the capacitor 108 may overlap the capacitor 128 in a direction substantially vertical to the top surface of the semiconductor substrate 102. As a result, the capacitance can be increased without taking up larger area. In addition, the capacitor 108 and the capacitor 128 may vertically overlap the conductive vias 116 and the conductive vias 136.

Then, as shown in FIG. 1D, the semiconductor substrate 122 is removed, in accordance with some embodiments. The semiconductor substrate 122 may be removed by performing a grinding process to thin the semiconductor substrate 122, and then using an etch process to remove the residual semiconductor substrate 122. For example, the etch process may be a wet etch process using a wet etchant including tetramethylammonium hydroxide (TMAH), ammonium hydroxide (NH₄OH), potassium hydroxide (KOH), the like, or a combination thereof.

Afterwards, a dielectric layer 142 is formed over the insulating layer 124, in accordance with some embodiments. The dielectric layer 142 may be formed of dielectric materials, including silicon oxide, silicon nitride, silicon oxynitride, the like, or a combination thereof, and may be formed by a deposition process.

Then, a plurality of conductive vias 144 and 146 are formed in the dielectric layer 142, in accordance with some embodiments. The conductive vias 144 and 146 may be formed by forming openings in the dielectric layers 132 and 142, and then filling the openings with conductive materials using a deposition process. The conductive materials may be metal, including tungsten, titanium, tantalum, ruthenium, cobalt, copper, aluminum, platinum, tin, silver, gold, the like, an alloy thereof, or a combination thereof.

The conductive vias 144 and 146 may be disposed on opposite sides of the capacitor 128. In the direction vertical to the top surface of the semiconductor substrate 102, the length of the conductive via 146 may be greater than the length of the conductive via 144. The length of the conductive via 146 may be greater than the total length of the conductive via 144 and the capacitor 128.

Afterwards, a conductive layer 148 may be formed over the conductive via 144, and a conductive layer 150 may be formed over the conductive vias 146. The conductive layer 148 may be electrically coupled to the first metal layer 126 through the conductive via 144, and the conductive layer 150 may be electrically coupled to the second metal layer 130 through the conductive vias 146. The conductive layers 148 and 150 may each independently be formed of metal, including tungsten, titanium, tantalum, ruthenium, cobalt, copper, aluminum, platinum, tin, silver, gold, the like, an alloy thereof, or a combination thereof, and may be formed by a deposition process.

Then, a conductive pad 152 is formed over the conductive layer 148, and a conductive pad 154 is formed over the conductive layer 146, in accordance with some embodiments. The conductive pad 152 may be electrically coupled to the conductive layer 148, and the conductive pad 154 may be electrically coupled to the conductive layer 146.

The conductive pads 152 and 154 may each independently be formed of metal, including tungsten, titanium, tantalum, ruthenium, cobalt, copper, aluminum, platinum, tin, silver, gold, the like, an alloy thereof, or a combination thereof, and may be formed by a deposition process.

Afterwards, a plurality of conductive connectors (not illustrated) may be formed over the conductive pads 155 and 154 and may be electrically coupled to the conductive pads 155 and 154. The conductive connectors may include microbumps, wire bonds, copper pillar bumps, the like, or a combination thereof.

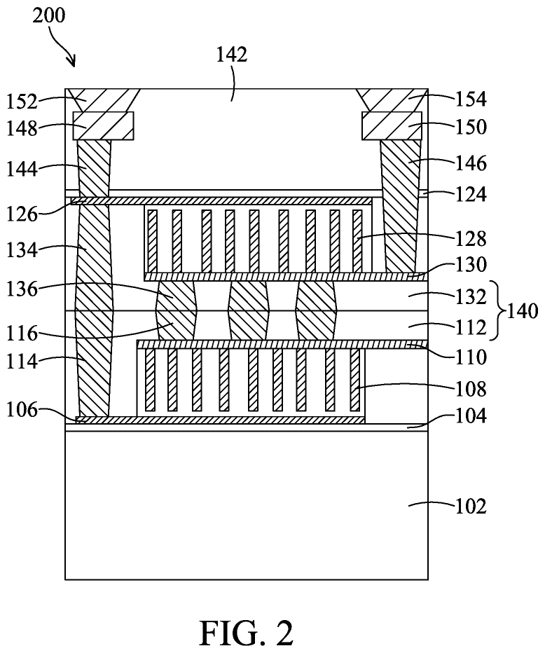

FIG. 2 is a cross-sectional view of a semiconductor structure 200 in accordance with some embodiments of the present disclosure. It should be noted that the semiconductor structure 200 may include the same or similar components as that of the semiconductor structure 100, which is illustrated in FIG. 1D, and for the sake of simplicity, those components will not be discussed in detail again. In the following embodiments, conductive vias have tapered sidewalls.

Openings for the conductive vias 114, 116, 134, 136, 144, and 146 may be tapered, which allows for a uniform filling of the openings when the conductive materials are deposited into the openings. As shown in FIG. 2, the widths of the conductive vias 114, 116, 144, and 146 may decrease in a direction toward the semiconductor substrate 102, and the widths of the conductive vias 134 and 136 may increase in the direction toward the semiconductor substrate 102.

In summary, the semiconductor structure according to the present disclosure includes a capacitor structure, which includes capacitors stacked with a hybrid-bonded structure. As a result, the capacitance density can be increased.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor structure, comprising:
a semiconductor substrate;
a first capacitor disposed over the semiconductor substrate;
a first conductive via disposed over the first capacitor;
a second conductive via bonded to the first conductive via;
a second capacitor disposed over the second conductive via; and
a first conductive pad and a second conductive pad disposed over the second capacitor and electrically coupled to the first capacitor and the second capacitor.

2. The semiconductor structure as claimed in claim 1, further comprising:
a first metal layer disposed over the second capacitor and electrically coupled to the first conductive pad; and
a second metal layer disposed between the second capacitor and the second conductive via and electrically coupled to the second conductive pad.

3. The semiconductor structure as claimed in claim 2, further comprising:
a third conductive via electrically coupling the first metal layer to the first conductive pad; and
a fourth conductive via electrically coupling the second metal layer to the second conductive pad.

4. The semiconductor structure as claimed in claim 3, wherein a length of the fourth conductive via is greater than a length of the third conductive via in a direction vertical to a top surface of the semiconductor substrate.

5. The semiconductor structure as claimed in claim 3, wherein the third conductive via and the fourth conductive via are disposed on opposite sides of the second capacitor.

6. The semiconductor structure as claimed in claim 1, wherein the first capacitor vertically overlaps the second capacitor.

7. The semiconductor structure as claimed in claim 1, further comprising:
a first dielectric layer surrounding the first capacitor and the first conductive via; and
a second dielectric layer surrounding the second capacitor and the second conductive via and bonded to the first dielectric layer.

8. The semiconductor structure as claimed in claim 1, further comprising:
a plurality of conductive connectors disposed over the first conductive pad and the second conductive pad and electrically coupled to the first capacitor and the second capacitor,
wherein the conductive connectors comprise microbumps, wire bonds, copper pillar bumps, or a combination thereof.

9. A semiconductor structure, comprising:
a semiconductor substrate;
a first metal layer disposed over the semiconductor substrate;
a first capacitor disposed over the first metal layer;
a second metal layer disposed over the first capacitor;
a third metal layer disposed over the second metal layer and electrically coupled to the second metal layer;
a second capacitor disposed over the third metal layer and vertically overlapping the first capacitor; and
a fourth metal layer disposed over the second capacitor and electrically coupled to the first metal layer.

10. The semiconductor structure as claimed in claim 9, further comprising:
a first conductive via electrically coupling the first metal layer to the fourth metal layer; and
a second conductive via electrically coupling the second metal layer to the third metal layer.

11. The semiconductor structure as claimed in claim 10, wherein a length of the first conductive via is greater than a length of the second conductive via in a direction vertical to a top surface of the semiconductor substrate.

12. The semiconductor structure as claimed in claim 10, wherein the second capacitor vertically overlaps the second conductive via.

13. The semiconductor structure as claimed in claim 10, wherein a first width of a middle portion of the first conductive via is greater than a second width of a top portion of the first conductive via.

14. The semiconductor structure as claimed in claim 9, further comprising:
a first conductive via electrically coupled to the fourth metal layer; and
a second conductive via electrically coupled to the third metal layer.

15. The semiconductor structure as claimed in claim 14, wherein a length of the second conductive via is greater than a total length of the first conductive via and the second capacitor in a direction vertical to a top surface of the semiconductor substrate.

16. The semiconductor structure as claimed in claim 9, further comprising a hybrid-bonding structure disposed between the second metal layer and the third metal layer.

17. A semiconductor structure, comprising:
a semiconductor substrate;
a first capacitor disposed over the semiconductor substrate;
a second capacitor disposed over and vertically overlapping the first capacitor; and
a hybrid-bonding structure disposed between the first capacitor and the second capacitor and electrically coupling the first capacitor to the second capacitor.

18. The semiconductor structure as claimed in claim 17, wherein the hybrid-bonding structure comprises:
a first conductive via disposed over the first capacitor;
a first dielectric layer surrounding the first conductive via;
a second conductive via disposed below the second capacitor; and
a second dielectric layer surrounding the second conductive via.

19. The semiconductor structure as claimed in claim 18, wherein the first conductive via has a first width decreasing in a direction toward the semiconductor substrate, and the second conductive via has a second width increasing in the direction toward the semiconductor substrate.

20. The semiconductor structure as claimed in claim 17, wherein the hybrid-bonding structure comprises:
a first conductive via adjacent to the first capacitor;
a first dielectric layer surrounding the first conductive via and the first capacitor;
a second conductive via adjacent to the second capacitor; and
a second dielectric layer surrounding the second conductive via and the second capacitor.
